(19) United States
(12) Patent Application Publication
(10) Pub. No.: US 2007/0272955 A1
(43) Pub. Date: Nov. 29, 2007

(54) Reliable Contacts

(75) Inventors: Dongzhi Chi, Singapore (SG); Ka Yau Lee, Singapore (SG); Tek Po Rinus Lee, Singapore (SG); Siao Li Liew, Singapore (SG); Hai Biao Yao, Singapore (SG)

Correspondence Address: HORIZON IP PTE LTD, 8 KALLANG SECTOR, EAST WING, 7TH FLOOR, SINGAPORE 349282, 349282, SG

(73) Assignee: Agency for science, Technology and Research, Singapore (SG)

(21) Appl. No.: 11/572,632

(22) PCT Filed: Jul. 27, 2004
(86) PCT No.: PCT/SG04/00220

§ 371 Date: Jan. 25, 2007

(51) Int. Cl. H01L 21/44; H01L 29/94

(52) U.S. Cl. 257/288; 438/666; 257/E29.345; 257/E21.476; 257/E21.477

(57) ABSTRACT

A nickel-based germanide contact includes a processing material that inhibits agglomeration of nickel-based germanide during processing to form the contact as well as during post-germanidation processes. The processing material is either in the form of a capping layer over the nickel layer or integrated into the nickel layer used to form the nickel-based contact. Reducing agglomeration improves electrical characteristics of the contact.

### FIELD OF THE INVENTION

The invention relates generally to the formation of germanide contacts used in, for example, integrated circuits (ICs). More particularly, the invention relates to improved formation of nickel-based germanide contacts used in integrated circuits.

### BACKGROUND OF THE INVENTION

FIG. 1 shows a portion 100 of a conventional CMOS IC. The portion includes first and second complementary transistors 120 and 140 formed on a silicon substrate 101. The first transistor is an n-MOS transistor formed on a deep p-doped well 121 while the second transistor is a p-MOS transistor formed on a deep n-doped well 141. Beneath the n-MOS transistor is a shallow p-doped well 122 while a shallow n-doped well is located below the p-MOS transistor 142. Shallow trench isolations 160 are used to isolate the transistors. Each transistor includes source (123 or 143), drain (124 or 144), and gate (125 or 145) electrodes. For an n-MOS transistor, the source, drain and gate electrodes are doped with n-type dopants, such as P. As for the p-MOS transistor, the source, drain, and gate electrodes are doped with p-type dopants, such as B.

To reduce contact resistance in, for example, the source, drain, and gate electrodes of transistors, titanium or cobalt silicide is used. Titanium and cobalt silicides are used as contacts 170 due to their good electrical properties and relatively high thermal stability. The metal silicide contacts are formed using self-aligned salicide processes. As part of the self-aligned process, dielectric side-wall spacers (128 and 148) on the sides of the gate electrodes may be used. Salicide processes are described in, for example, Sze, “ULSI Technology”, McGraw-Hill (1996), which is herein incorporated by reference for all purposes.

For high-speed applications, germanium-based substrates are employed, such as germanium or germanium-silicon. Germanium-based substrates are advantageous for high-speed applications due to their high carrier mobility characteristics, which are conducive for large drive currents. To form contacts for source, drain, and gate electrodes in germanium-based substrates, metal germanide processes are used.

Titanium and cobalt metals, which are widely used to form silicide contacts, are incompatible with germanide processes. This is because forming titanium or cobalt contacts with good electrical characteristics (e.g., low resistivity) requires relatively high annealing temperatures which are detrimental to germanium-based applications. For example, high temperatures cause evaporation of germanium or, where intentionally strained materials are used, undesirably relax the strain in such materials.

From the foregoing discussion, it is desirable to provide an improved germanide contact for use in ICs.

### SUMMARY OF THE INVENTION

The invention relates generally to fabrication of, for example, integrated circuits. In one embodiment, a substrate is provided. The substrate includes an active region comprising germanium. A nickel-based contact is formed on the active region. The nickel-based contact comprises a processing material which inhibits agglomeration of nickel during processing. This results in improved electrical characteristics of the nickel-based contact.

In one embodiment, a nickel layer is deposited over the substrate, covering the active region. A capping layer comprising the processing material is formed over the nickel layer. In another embodiment, the nickel layer comprises the processing material, forming a nickel alloy layer. The substrate is then processed by annealing to form the nickel-based contact. The processing material of the capping layer or the contact layer inhibits agglomeration of nickel during anneal to form the nickel-based contact.

### BRIEF DESCRIPTION OF DRAWINGS

FIG. 1 shows a portion of a conventional CMOS IC; and

FIGS. 2-6 show a process for forming contacts in accordance with one embodiment of the invention.

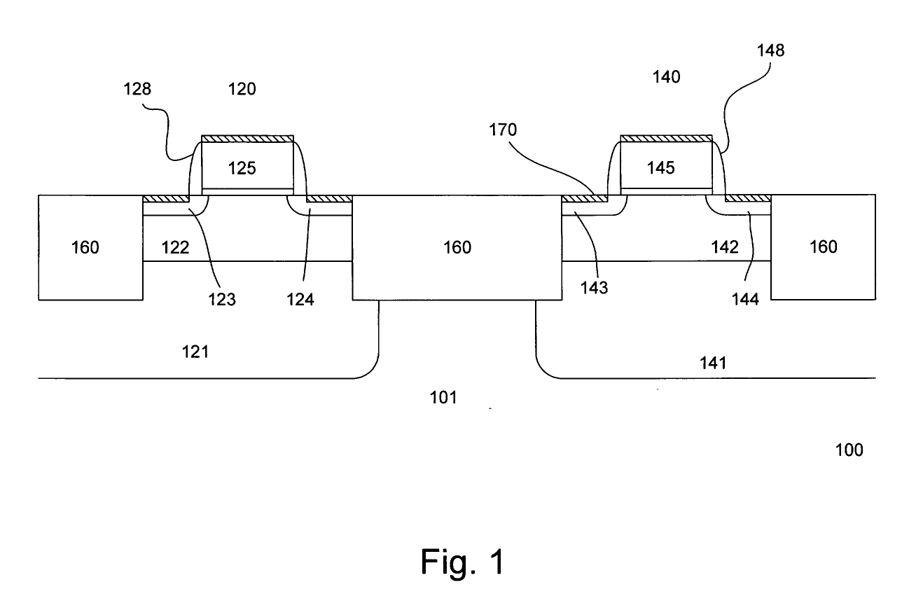

### DETAILED DESCRIPTION OF THE INVENTION

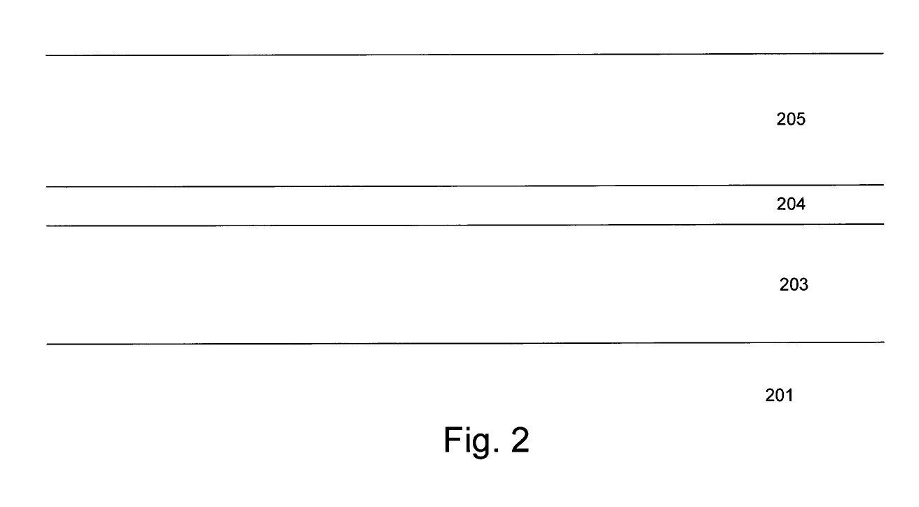

FIGS. 2-6 show a process for forming nickel-based contacts in accordance with one embodiment of the invention. Referring to FIG. 2, a cross-section of a portion of a substrate 201 is shown. The substrate serves to form integrated circuit components. In one embodiment, the substrate comprises a multi-layered substrate in which at least the top or surface layer comprises germanium. For example, the multi-layered substrate comprises a germanium-on-insulator substrate. The germanium-on-insulator substrate may include a silicon bulk substrate 203 with a top layer 205 comprising germanium separated by an insulator layer 204, such as silicon oxide. The top layer of the substrate comprises, for example, a single crystalline material, a polycrystalline or amorphous material, or a combination thereof. The germanium layer can be strained or relaxed. Providing a surface comprising germanium over a silicon-germanium bulk layer is also useful.

In another embodiment, at least the top or surface layer of the substrate comprises silicon-germanium. Preferably, the silicon-germanium layer comprises Si₁₋ₓGeₓ where x is less than 50 atomic percent. The silicon-germanium layer can be strained or relaxed. The substrate can also include silicon-germanium over silicon-germanium having different percentages of Ge. Providing a single-layered substrate comprising germanium, including silicon-germanium is also useful. In yet another embodiment, at least a portion of the top surface of the substrate comprises germanium, including silicon-germanium.

Alternatively, a thin strained layer of silicon provided on top of the germanium layer is also useful. The silicon layer should be sufficiently thin to maintain tensile strain. Typically, the thickness of the thin strained silicon layer is less than 100 nm.

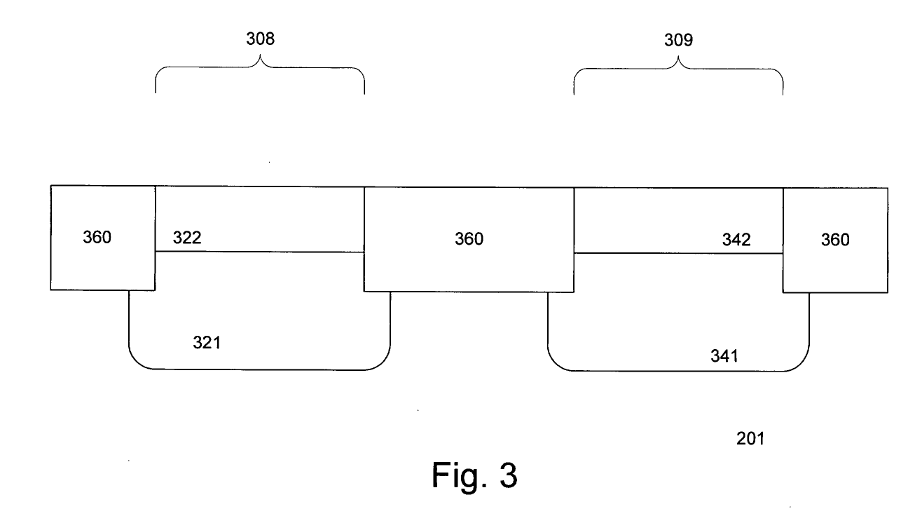

Referring to FIG. 3, a portion of the substrate is prepared with doped wells for transistors. As shown, the wells are prepared for a CMOS application. Other types of applications are also useful. In one embodiment, active regions 308 and 309 for a p-MOS and n-MOS transistor, respectively, are provided. The active region of the p-MOS transistor includes a deep p-well 321 and shallow n-well 322. The active region of the n-MOS transistor includes a deep n-well 341 and a shallow p-well 342. Separating the active regions are shallow trench isolations (STIs) 360.

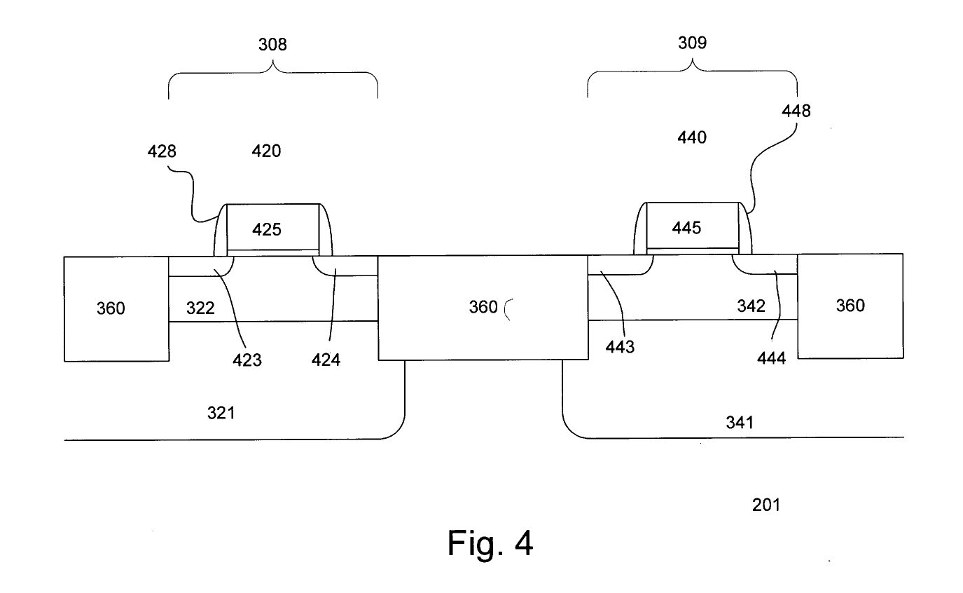

As shown in FIG. 4, the process continues by forming p-MOS and n-MOS transistors 420 and 440 in active regions 308 and 309. The transistors each includes first and second diffusion regions (423-424 or 443-444) and a gate (425 or 445). The diffusion regions of the p-MOS transistor comprise p-type dopants while the diffusion regions of the n-MOS transistor comprise n-type dopants. The gates of the transistors comprise germanium. Typically, the gate comprises polycrystalline germanium. Other types of materials, such as silicon or silicon-germanium, are also useful. Preferably, the gates are doped with dopants. In one embodiment, the gates of the transistors are doped with p-type dopants. Doping the gates with other dopants is also useful. It may also be useful to dope the gates of the p-MOS and n-MOS transistors with different types of dopants. Beneath the gate is a gate oxide layer. The gate oxide layer comprises, for example, thermally grown silicon oxide. Other types of gate oxide materials are also useful. In one embodiment, insulating sidewall spacers 428 and 448 are provided on the sides of the p-MOS and n-MOS gates.

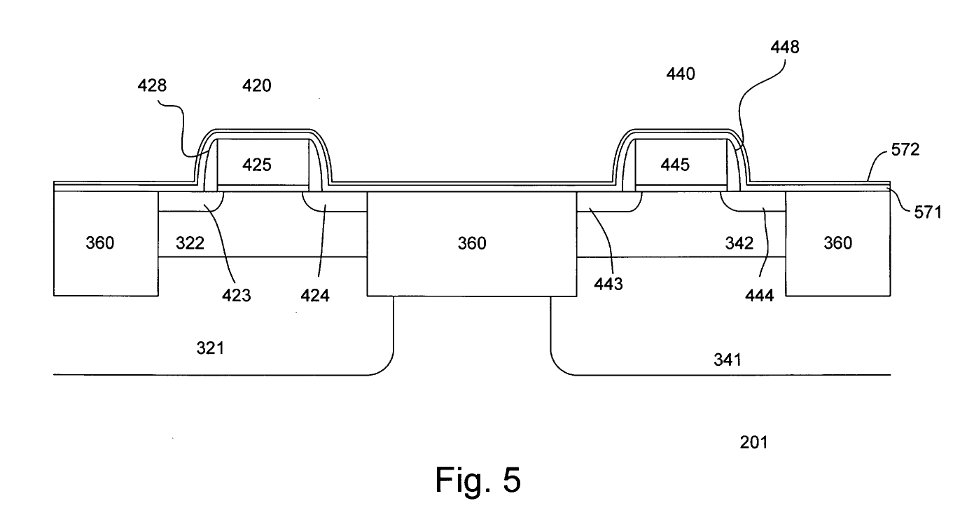

Referring to FIG. 5, the process continues by depositing materials for forming nickel-based germanide contacts on the diffusion regions and gates. In one embodiment, a nickel layer 571 is deposited on the substrate. Various techniques can be used to form the nickel layer, such as sputtering, including magnetron sputtering. The nickel layer is sputtered, for example, at a pressure of about 5×10⁻⁷ Torr at about room temperature. Other techniques or parameters for forming the nickel layer are also useful. The thickness of the nickel layer is about 5-100 nm. Preferably, the thickness of the nickel layer is less than about 50 nm. Other thicknesses may also be useful.

A capping layer 572 is formed over the nickel layer. The capping layer, in one embodiment, comprises a material which inhibits the agglomeration of the nickel germanide layer. In one embodiment, the material of the capping layer is insoluble in the nickel-based contact. In one embodiment, the capping layer comprises Mo, Ta, Ti, W, Zr or a combination thereof. Other materials that can inhibit agglomeration of nickel germanide at processing temperatures are also useful. In another embodiment, the capping layer comprises a material which is soluble in the nickel-based contact, such as Pd and/or Pt. The use of a combination of soluble and insoluble materials in the nickel-based contact to form the capping layer is also useful.

Various techniques can be used to form the capping layer, such as sputtering, including magnetron sputtering. The sputtering, in one embodiment, is performed at room temperature. Other techniques or parameters for forming the capping layer such as thermal and electron-beam evaporation are also useful.

The thickness of the capping layer should be sufficient to inhibit agglomeration in the layer at temperatures greater than about 500° C. Preferably, the thickness of the capping layer should be sufficient to inhibit agglomeration in the layer at least up to temperatures of about 700° C. In one embodiment, the thickness of the capping layer should be sufficient to inhibit agglomeration in the layer at temperatures from about 500-700° C. The thickness of the capping layer, for example, is less than or equal to about 50 nm. Preferably, the thickness of the capping layer is about 5 nm.

After the contact layers are formed, the substrate is annealed to form the contacts. The annealing causes the materials of the contact layers and substrate to react, forming nickel-based germanide or nickel-based germanosilicide contacts in substrate areas comprising germanium. For underlying layer of germanium for the contact layers, nickel-based monogermanide contacts are formed while nickel-based germanosilicide contacts are formed for silicon germanium underlying layers. In one embodiment, the annealing comprises a rapid thermal anneal (RTP). Other types of annealing are also useful. The RTP is performed at a temperature of about 200° C. to at least about 700° C. for about 1-100 seconds. Preferably, the RTP is performed at a temperature of about 280° C. to at least about 500° C. The ambient of the RTP is, for example, nitrogen. Other types of ambients, such as vacuum, He, Ar are also useful. Other types of inert gases can also be used.

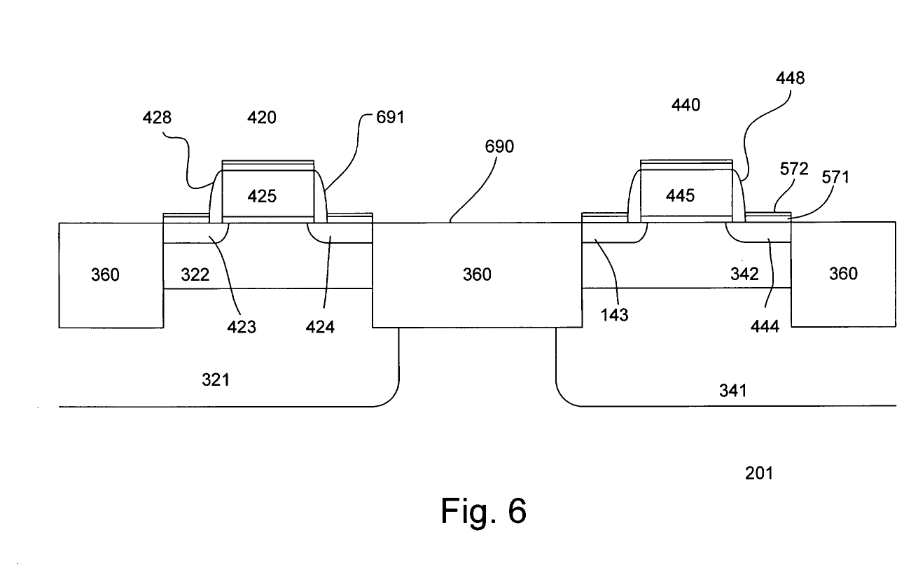

Referring to FIG. 6, the contact layers are patterned to leave portions of the contact layers in areas where contacts are formed. In one embodiment, materials of the contact layers are removed from areas 690 and 691 above the STIs and sidewall spacers, leaving the contact layers over the surface of the diffusion regions and gates. The contact layers are patterned by, for example, conventional mask and etch techniques. For example, a photoresist layer is deposited and patterned to expose portions of the layers to be removed, followed by an etch process to remove the layers unprotected by the photoresist layer. In another embodiment, the contact layers are patterned prior to the annealing process for forming the contacts.

In an alternative embodiment, a contact layer comprising nickel-based alloy is deposited over the substrate prepared with the transistors, as described in, for example, FIG. 4. The nickel-based alloy comprises NiY, where Y comprises a material selected from a material which inhibits agglomeration of the contact layer. In one embodiment, Y comprises a material which is insoluble in nickel-based contact. In one embodiment, Y comprises Mo, Ta, Ti, Mo, W, Zr or a combination thereof. Other materials which are insoluble in the nickel-based contact are also useful. In another embodiment, Y comprises a material which is soluble in the nickel-based contact, such as Pd and/or Pt. Providing Y comprising a combination of both soluble and insoluble materials in the nickel-based contact is also useful. The thickness of the nickel-based alloy layer is, for example, about 5-100 nm. Preferably, the thickness of the nickel-based alloy layer is less than 50 nm.

In one embodiment, the percentage of Y should be sufficient to inhibit agglomeration in the layer at temperatures greater than about 500° C. Preferably, the percentage of Y should be sufficient to inhibit agglomeration in the layer at least up to temperatures of about 700° C. More preferably, the percentage of Y should be sufficient to inhibit agglomeration in the layer at temperatures from about 500-700° C. The percentage of Y, for example, is about 0.1 to 50 atomic percent. Preferably, the percentage of Y is less than about 20 atomic percent.

After the nickel-based alloy layer is formed, the process continues to form the contacts by annealing the contact layer. The annealing process, for example, comprises RTP as previously described. Contacts are formed in regions comprising nickel and germanium. In areas where germanium is absent (e.g., above the STI), no reaction occurs. Unreacted portions of the nickel layer are selectively removed using, for example, a wet etch selective to the reacted portions of the nickel layer. As a result, self-aligned nickel germanide or nickel germanosilicide contacts are formed.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claimed is:

1. A method of fabricating a contact, the method comprising:
providing a substrate comprising at least an active region comprising germanium;
depositing a contact layer comprising nickel on the active region;
providing a processing material to the contact layer; and
processing the substrate to form a nickel-based contact, the processing includes annealing the substrate to cause a reaction to form the nickel-based contact, wherein
the processing material inhibits agglomeration of the contact layer during processing.

2. The method of claim 1 wherein the substrate comprises a multi-layered substrate in which a top surface layer comprises germanium or silicon-germanium.

3. The method of claim 1 wherein the substrate comprises germanium or silicon-germanium.

4. The method of any of claims 1-3 wherein the processing material is insoluble in nickel-based contact.

5. The method of claim 4 wherein the processing material comprises Ta, Ti, Mo, W, Zr or a combination thereof.

6. The method of any of claims 1-5 wherein the providing the processing material comprises forming a capping layer over the contact layer.

7. The method of claim 6 wherein the thickness of the capping layer is sufficient to inhibit agglomeration at temperatures of greater than or equal to about 500° C.

8. The method of claim 6 wherein the thickness of the capping layer is sufficient to inhibit agglomeration at temperatures of at least up to about 700° C.

9. The method of claim 6 wherein the thickness of the capping layer is less than or equal to about 50 nm.

10. The method of any of claims 1-5 wherein the providing the processing material comprises integrating the processing material into the step of depositing the contact layer to form a nickel-based alloy contact layer comprising nickel and the processing material.

11. The method of claim 10 wherein the processing material in the nickel-based alloy is less than about 50 atomic percent.

12. The method of claim 10 wherein a percentage of the processing material in the contact layer is sufficient to inhibit agglomeration during processing at temperatures of greater than or equal to about 500° C.

13. The method of claim 10 wherein a percentage of the processing material in the contact layer is sufficient to inhibit agglomeration during processing at temperatures of at least up to about 700° C.

14. The method of any of claims 1-3 wherein the processing material comprises a combination of materials which are soluble and insoluble in the nickel-based contact.

15. The method of any of claims 1-3 wherein the processing material comprises Pt and/or Pd.

16. An integrated circuit comprising:
a substrate having at least an active region comprising germanium;
a contact coupled to the active region, the contact comprising nickel; and
a processing material in contact with the contact, wherein the processing material inhibits agglomeration of the nickel in the contact during processing to form the contact.
